(19) United States
(12) Patent Application Publication
(10) Pub. No.: US 2010/0065836 A1
(43) Pub. Date: Mar. 18, 2010

(54) RESISTIVE MEMORY DEVICE AND METHOD OF FABRICATING THE SAME

(75) Inventor: Yu-Jin Lee, Icheon-si (KR)

Correspondence Address: LOWE HAUPTMAN HAM & BERNER, LLP, 1700 DIAGONAL ROAD, SUITE 300, ALEXANDRIA, VA, 22314, US

(73) Assignee: Hynix Semiconductor Inc., Icheon-si (KR)

(21) Appl. No.: 12/342,774

(22) Filed: Dec. 23, 2008

(30) Foreign Application Priority Data
Sep. 18, 2008 (KR) 10-2008-0091526

(51) Int. Cl. H01L 29/12; H01L 29/00; H01L 21/00; H01L 21/44

(52) U.S. Cl. 257/43; 257/536; 438/104; 438/597; 977/762; 977/943; 257/E21.001; 257/E29.068; 257/E21.476; 257/E29.001

(57) ABSTRACT

A resistive memory device includes an insulation layer over a substrate, a nanowire penetrating the insulation layer, a resistive layer formed over the insulation layer and contacting with the nanowire, and an upper electrode formed over the resistive layer.

### CROSS-REFERENCE TO RELATED APPLICATIONS

The present application claims priority of Korean patent application number 10-2008-0091526, filed on Sep. 18, 2008, which is incorporated herein by reference in its entirety.

### BACKGROUND

The disclosure relates to a memory device and a method of fabricating such a memory device, and more particularly, to a resistive memory device having changeable resistance, like a nonvolatile resistive random access memory (ReRAM) device, and a method of fabricating the same.

Recently, next-generation memory devices as substitutes for dynamic random access memory (DRAM) devices and flash memory devices have been researched.

One of the next-generation memory devices is a resistive memory device using a material, such as a resistive layer, capable of switching between two resistance states. The resistive layer may include binary oxide including transition metal-based oxide or perovskite-based oxide.

The structure of the resistive memory device and the mechanism of resistance switching will be described hereinafter.

In general, the resistive memory device has a structure including an upper electrode, a lower electrode and a resistive layer formed between the upper electrode and the lower electrode. The upper and the lower electrodes include metal materials used for electrodes of known memory devices. Furthermore, the resistive layer includes binary oxide including transition metal-based oxide or perovskite-based oxide, as described hereinbefore.

When a predetermined voltage is supplied to the upper and lower electrodes, depending on the supplied voltage, a filamentary current path may be generated in the resistive layer or the filamentary current path previously generated may disappear. When the filamentary current path is generated in the resistive layer, it represents a set-state. The set-state means that a resistance of the resistive layer is low. Furthermore, when the filamentary current path in the resistive layer disappears, it represents a reset-state, which means that a resistance of the resistive layer is high. Different data such as bit data ‘0’ or ‘1’ may be stored in the resistive memory device according to the resistance state of the resistive layer, since the resistive layer is switched between the stable set-state and the stable reset-state.

However, since the filament current paths are randomly formed in the resistive layer, even if the same voltage is supplied to the upper and the lower electrodes, the number and location of the filament current paths are not the same, but always change. Because of the irregular generation of the filament current paths, uniformity of the resistive memory device is deteriorated. That is, its set-current and reset-current (I_{SET}/I_{RESET}) or set-voltage and reset-voltage (V_{SET}/V_{RESET}) are not uniform.

Moreover, when the reset current is not uniform and has an excessively high value, reliability of the resistive memory device may be deteriorated and its power consumption may be increased.

In an article by I. G. Baek et al., entitled “Multi-layer Cross-point Binary Oxide Resistive Memory (OxRRAM) for Post-NAND Storage Application,” IEEE, 2005, which is entirely incorporated by reference herein, a contact area between the resistive layer and the lower electrode can be decreased by forming the lower electrode in a plug shape in order to improve uniformity of the resistive memory device, more particularly, in order to decrease its reset current. Since a filament current path may be generated only in the portion of the resistive layer contacting the lower electrode, the filament current path generation can be controlled according to the contact area and the contact location between the lower electrode and the resistive layer.

According to the proposal of the article, when the lower electrode having the plug shape is used, it is important to decrease the size of the contact area between the lower electrode and the resistive layer in order to decrease the reset current and improve the integration ratio of the resistive memory device.

However, there is a limitation to how far the size of the lower electrode having the plug shape can be decreased. In a known method of fabricating the lower electrode having a plug shape, a hole is formed by etching a portion of an insulation layer and a metal material is filled in the hole, or the metal material is formed over the hole and then patterned. However, since the processes for the known method, such as photolithography and etching processes are limitative, the size of the lower electrode having the plug shape cannot be decreased below a certain limit.

Therefore, even if the method and/or the plug shaped lower electrode proposed in the article is/are used, it is still difficult to improve uniformity of the resistive memory device and to decrease the reset current to reach certain levels. Thus, a new technology which can further improve uniformity of the resistive memory device and decrease its reset current is needed.

### SUMMARY

In accordance with an aspect, there is provided a resistive memory device. The resistive memory device includes an insulation layer over a substrate, a nanowire defining a lower electrode and penetrating the insulation layer, a resistive layer formed over the insulation layer and contacting the nanowire, and an upper electrode formed over the resistive layer.

In accordance with another aspect, there is provided a method of fabricating a resistive memory device. The method includes forming a nanowire penetrating an insulation layer over a substrate to define a lower electrode, forming a resistive layer over the insulation layer to contact the nanowire, and forming an upper electrode over the resistive layer.

In accordance with a further aspect, there is provided a method of forming an electrode for a resistive memory device that comprises a resistive layer sandwiched between said electrode and another electrode. The method comprises forming a catalyst layer over a substrate in a region where said electrode is to be formed, growing a nanowire from the catalyst layer to form said electrode, and burying the nanowire in an insulation layer.

### BRIEF DESCRIPTION OF THE DRAWINGS

Various embodiments are illustrated by way of example, and not by limitation, in the figures of the accompanying drawings.

FIG. 1 is a cross-sectional view of a resistive memory device in accordance with an embodiment.

FIGS. 2A to 2F are cross-sectional views describing a method of fabricating a resistive memory device in accordance with an embodiment.

FIGS. 3A to 3E are cross-sectional views describing a method of fabricating a resistive memory device in accordance with another embodiment.

FIG. 4 is a graph comparing characteristics of a resistive memory device according to some embodiments and a typical resistive memory device.

### DESCRIPTION OF EMBODIMENTS

In the figures, the dimensions of layers and regions are exaggerated for clarity of illustration. It will also be understood that when a layer is referred to as being “on/under” another layer or substrate, it can be directly on/under the other layer or substrate, or intervening layers may also be present. Likewise, when a layer is referred to as being ‘between’ two layers, it can be the only layer between the two layers, or one or more intervening layers may also be present. Like reference numerals refer to like elements throughout the drawings. In addition, different English alphabetical characters following a reference numeral of a layer refer to different states of the layer after one or more processing steps, such as an etch process or a polishing process.

FIG. 1 is a cross-sectional view of a resistive memory device in accordance with an embodiment.

Referring to FIG. 1, the resistive memory device includes a substrate 10, an insulation layer 11 formed over the substrate 10, one or more nanowires 12 penetrating the insulation layer 11, a resistive layer 13 formed over the insulation layer 11 and contacting with the nanowires 12, and an upper electrode 14 formed over the resistive layer 13. The nanowires 12 are used as the lower electrode in the resistive memory device.

When the nanowires 12 are used as the lower electrode, there are several advantages over the typical resistive memory device as will be described hereinafter.

A diameter of a nanowire ranges from 1 nm to 99 nm, and the diameter of the nanowire may be controlled, in some embodiments, by growing conditions of the nanowire. The location and the number of nanowires may be also controlled, in some embodiments, by the growing conditions of the nanowires.

When the nanowire 12 is used as the lower electrode, the dimension of such lower electrode compared with that of the lower electrode in a typical resistive memory device can be greatly decreased. Thus, the contact area of the resistance layer 13 and the nanowire 12 can be decreased. Therefore, the reset current can be decreased.

Since a filament current path can only be formed in the portion the resistive layer 13 contacting the nanowire 12, designated at ‘F’ in FIG. 1, the number and the location of the filament current paths can be controlled by controlling the number and location of the nanowires 12. This improves uniformity of the resistive memory device. Distribution of the set-current and reset-current (I_{SET}/I_{RESET}) or the set-voltage and reset-voltage (V_{SET}/V_{RESET}) of the resistive memory device can also be uniform.

Furthermore, the integration ratio of the resistive memory device can be improved since the area of the lower electrode can be decreased.

Each element of the resistive memory device will be described in detail hereinafter.

The substrate 10 may include a lower structure for controlling the resistive memory device. Although it is not illustrated in the drawings, the substrate 10 may include, as its lower structure, a selectable device electrically contacting the lower electrode of the resistive memory device. The selectable device may include a transistor or a diode.

The insulation layer 11 may include an oxide layer, and the upper electrode 14 may include at least a metal selected from the group consisting of Ni, Co, Ti, Al, Au, Pt, Ta, Cr, and Ag.

The resistive layer 13 may include a binary oxide selected from the group consisting of MgO, TiO₂, NiO, SiO₂, Nb₂O₅, HfO₂, CuO_{X} and ZnO_{X}, or a perovskite-based oxide.

The nanowire 12 used as the lower electrode may include a metal nanowire selected from the group consisting of a Cu nanowire, an Ag nanowire and a Fe nanowire. Furthermore, the nanowire 12 may include the above mentioned Cu, Ag or Fe nanowires doped with impurity or semiconductor nanowires doped with impurity. The impurity may include germanium Ge.

Moreover, since the diameter, the location and the number of the nanowires 12 may be controlled by the growth conditions, the diameter, the location and the number of the nanowires 12 should be controlled in some embodiments by considering the size of the resistive memory device, the desired level of the reset current and the current sensing margin. For example, it is desirable in some embodiments that the diameter of the nanowire 12 is in a range of approximately 1 nm to approximately 30 nm. The number of the nanowires 12 may be one or more. When the diameter of the nanowire 12 is comparatively large (approximately 20 nm), it is desirable that the lower electrode includes only one nanowire 12. Furthermore, when the diameter of the nanowire 12 is comparatively small (approximately 10 nm), it is desirable that the lower electrode includes two or more nanowires 12.

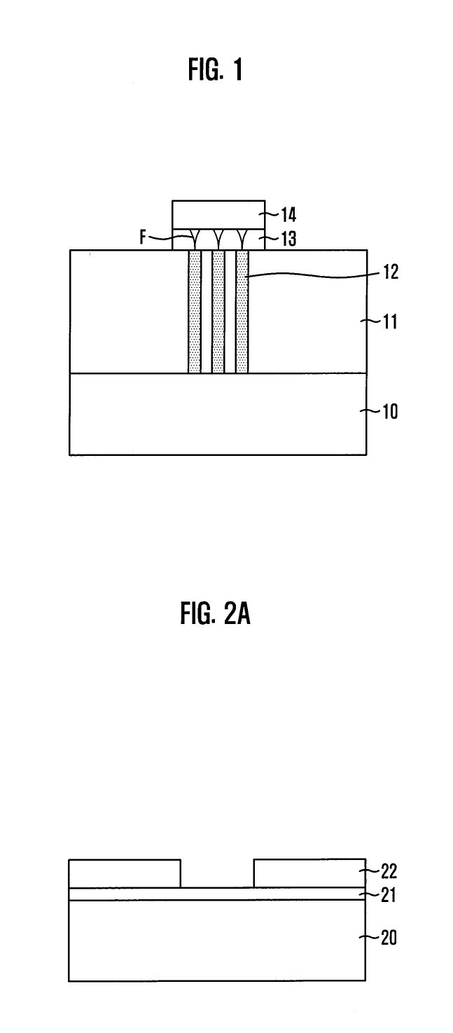

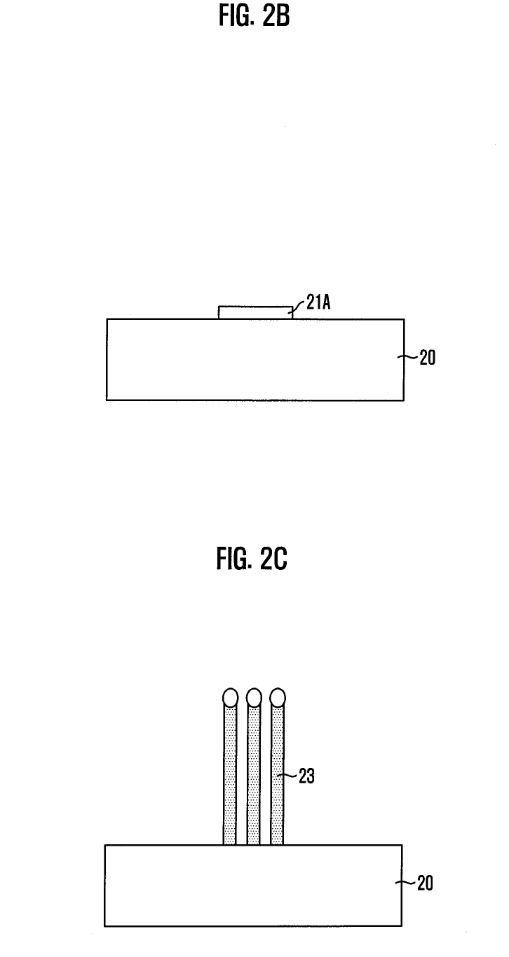

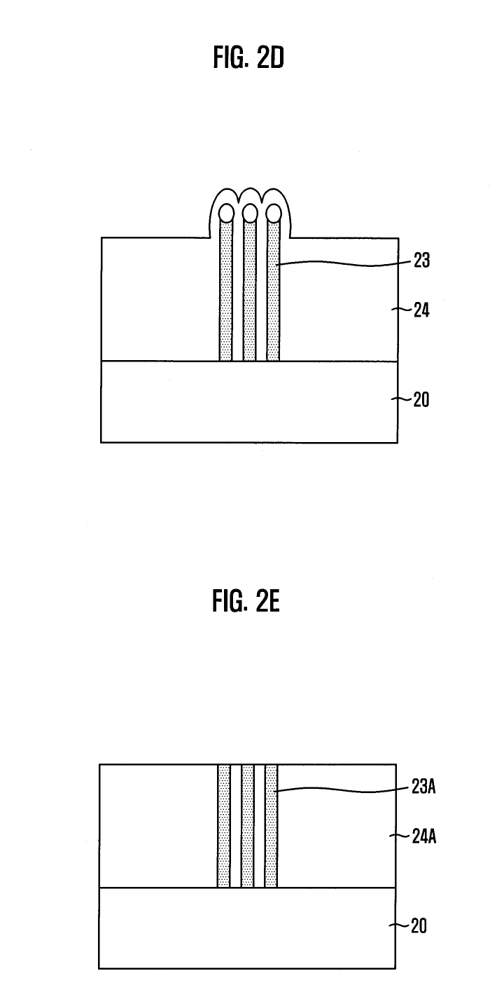

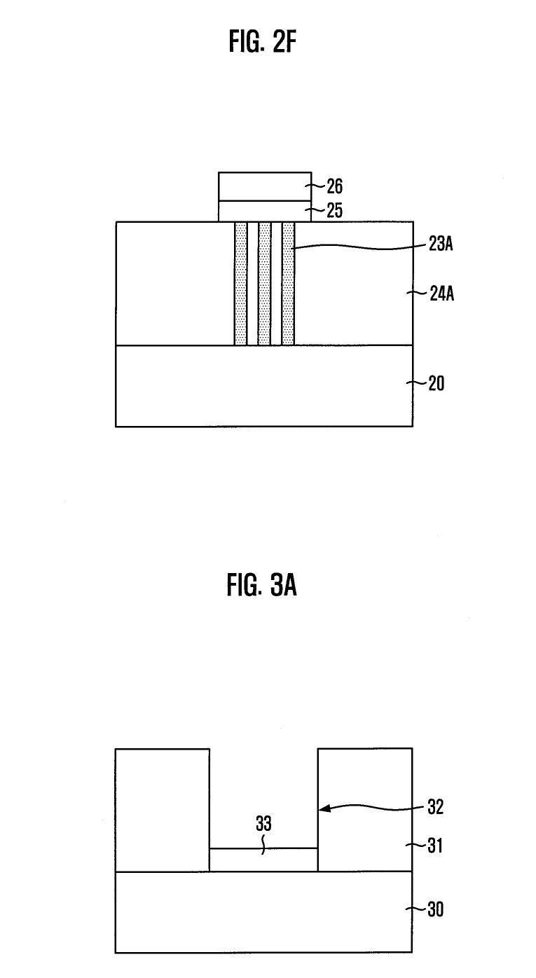

FIGS. 2A to 2F are cross-sectional views describing a method of fabricating a resistive memory device in accordance with an embodiment.

Referring to FIG. 2A, a catalyst layer 21 is formed over a substrate 20 having a certain lower structure. The catalyst layer 21 is used as a catalyst for growing at least a nanowire. The catalyst layer 21 in some embodiments includes a metal selected from the group consisting of Au, Pt and Pd and a thickness of the catalyst layer 21 ranges from approximately 10 Å to approximately 100 Å.

A photoresist pattern 22 is formed over the catalyst layer 21 in order to define a region where at least a nanowire is to be formed.

Referring to FIG. 2B, the catalyst layer 21 is etched by using the photoresist pattern 22 as an etch mask. Therefore, a catalyst pattern 21A is formed over a portion of the substrate 20, where one ore more nanowire(s) is/are to be formed, and then the remaining photoresist pattern 22 is removed.

Referring to FIG. 2C, nanowires 23 are grown based on the catalyst pattern 21A over the substrate 20. The growth of the nanowires 23 will be described in detail hereinafter.

Firstly, the catalyst pattern 21A having a thin layer structure is thermally treated at a predetermined temperature, and thus the catalyst pattern 21A has quantum dots having an nm-size according to the surface cohesion effect. The nanowires 23 are grown by injecting a source gas for a required material on the quantum dots. As described above, the nanowire 23 may include a metal nanowire or a semiconductor nanowire. Furthermore, impurity like Ge may be doped in-situ while the nanowires 23 are being grown.

Referring to FIG. 2D, an insulation layer 24 is formed over a first resultant structure including the nanowires 23. It is desirable in some embodiments that the insulation layer 24 includes an oxide layer.

As illustrated in FIG. 2D, the insulation layer 24 is generally formed along a profile of the first resultant structure at different heights, i.e., a height of the insulation layer 24 formed on the nanowires 23 is higher than other portions of the insulation layer 24. Thus, a planarization process is performed.

Referring to FIG. 2E, the planarization process is performed on a second resultant structure including the insulation layer 24 in order to level the insulation layer 24 and the nanowires 23 at the same height. The planarization process may include a chemical mechanical polishing (CMP) process. Reference numerals 23A and 24A represent the planarized nanowires and insulation layer, respectively.

Referring to FIG. 2F, a material layer for a resistive layer and a conductive layer for an upper electrode are sequentially formed over the planarized resultant structure, and then the material layer and the conductive layer are patterned. Thus, a resistive memory device is formed including a stack structure of the planarized nanowires 23A, a resistive pattern 25 and an upper electrode 26. The material layer for the resistive layer may include a binary oxide or a perovskite-based oxide.

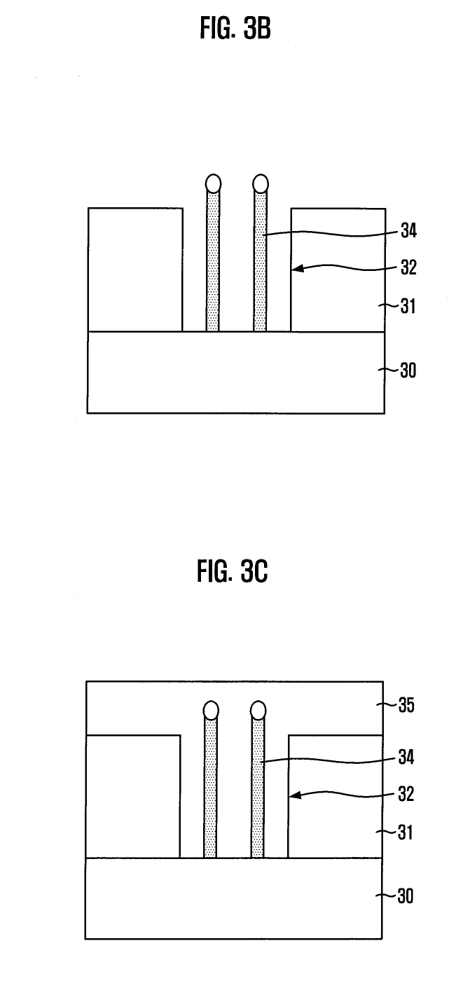

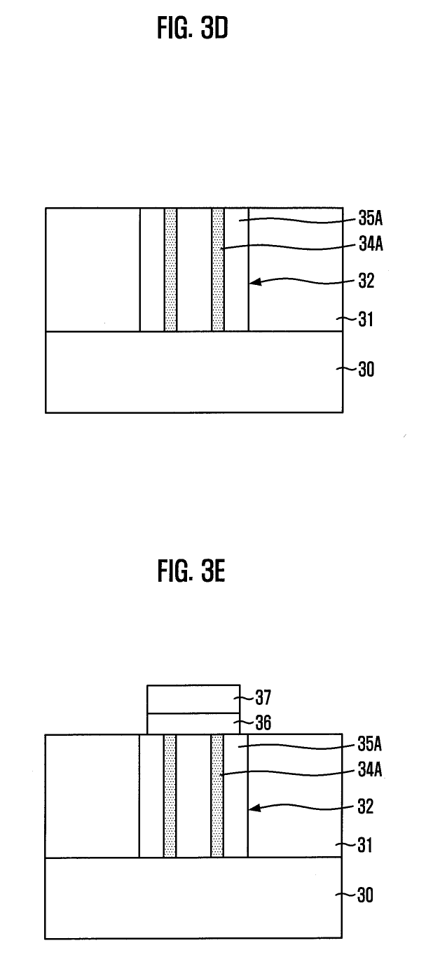

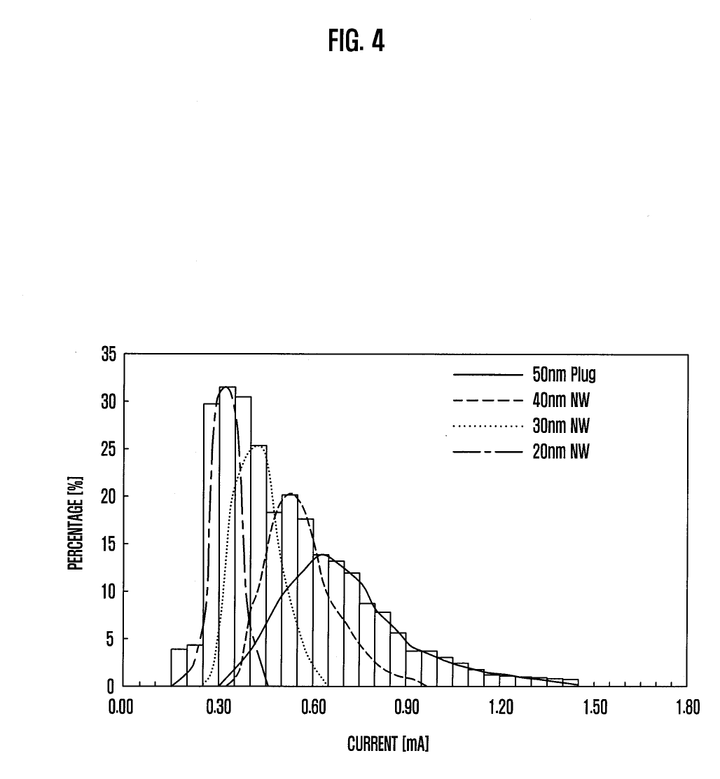

FIGS. 3A to 3E are cross-sectional views describing a method of fabricating a resistive memory device in accordance with another embodiment.

Referring to FIG. 3A, a first insulation layer 31 is formed over a substrate 30 having a certain lower structure. It is desirable in some embodiments that the first insulation layer 31 includes an oxide layer. A photoresist pattern (not shown) is formed over the first insulation layer 31 in order to define a region where at least a nanowire is to be formed, and then the first insulation layer 31 is etched by using the photoresist pattern as an etch barrier or mask, thereby forming an opening 32. Thus, a portion of the substrate 30 is exposed in the region where the nanowire(s) is/are to be formed.

A catalyst layer 33 is formed over the exposed portion of the substrate 30 in the opening 32. The catalyst layer 33 in some embodiments includes a metal selected from the group consisting of Au, Pt and Pd and a thickness of the catalyst layer 33 ranges from approximately 10 Å to approximately 100 Å.

Referring to FIG. 3B, nanowires 34 are grown based on the catalyst layer 33 over the substrate 30 in the opening 32. The growth of the nanowires 34 will be described in detail hereinafter.

Firstly, the catalyst layer 33 is thermally treated at a predetermined temperature, and thus the catalyst layer 33 has quantum dots having an nm-size. The nanowires 34 are grown by injecting a source gas for a required material on the quantum dots. As described above, the nanowire 34 may include a metal nanowire or a semiconductor nanowire. Furthermore, impurity like Ge may be doped in-situ while the nanowires 34 are being grown.

Referring to FIG. 3C, a second insulation layer 35 is formed over a resultant structure including the nanowires 34. It is desirable in some embodiments that the second insulation layer 35 includes the same material layer as the first insulation layer 31, e.g., an oxide layer.

Referring to FIG. 3D, a planarization process is performed on the resultant structure including the second insulation layer 35 in order to level the first insulation layer 31, the second insulation layer 35 and the nanowires 34 at the same height. The planarization process may include a CMP process. Reference numerals 34A and 35A represent the planarized nanowires and second insulation layer, respectively.

Referring to FIG. 3E, a material layer for a resistive layer and a conductive layer for an upper electrode are sequentially formed over the planarized resultant structure, and then the material layer and the conductive layer are patterned. Thus, a resistive memory device is formed including a stack structure of the planarized nanowires 34A, a resistive pattern 36 and an upper electrode 37. The material layer for the resistive layer may include a binary oxide or a perovskite-based oxide.

FIG. 4 is a graph comparing characteristics of the resistive memory device according to some embodiments and a typical resistive memory device.

Unlike a typical plug-type lower electrode which has a minimum diameter of approximately 50 nm because of the processing limitations discussed above, a diameter of the nanowire used as a lower electrode can be smaller than 50 nm, and it may be even as small as several nm. Simulation results showing the reset current when the plug-type lower electrode having a diameter of approximately 50 nm is used and the reset currents when nanowire lower electrodes having diameters smaller than 50 nm, e.g., 20 nm, 30 nm and 40 nm, respectively, are used are shown in FIG. 4.

Referring to FIG. 4, the reset current when the plug-type lower electrode is used has a range from approximately 0.3 mA to approximately 1.5 mA. A distribution of the reset current is large, that is, the value of the reset current is not uniform. Furthermore, the reset current may be as large as approximately 1.5 mA.

However, when the nanowire lower electrodes are used, as the diameters of the nanowires become smaller, the distribution of the reset currents also becomes smaller. Thus, the maximum value of the reset currents becomes smaller and the value of the reset currents is uniform.

Therefore, it is recognized that, when at least a nanowire is used as the lower electrode, uniformity of the resistive memory device can be improved and its reset current can be decreased.

While exemplary embodiments have been described, the embodiments are illustrative and not limitative. It will be apparent to those skilled in the art that various changes and modifications may be made.

What is claimed is:

1. A resistive memory device, comprising:
a substrate;
an insulation layer over the substrate;
a nanowire defining a lower electrode and penetrating the insulation layer;
a resistive layer formed over the insulation layer and contacting the nanowire; and
an upper electrode formed over the resistive layer.

2. The device of claim 1, wherein the resistive layer includes a binary oxide or a perovskite-based oxide.

3. The device of claim 1, wherein the nanowire includes a metal nanowire or a semiconductor nanowire.

4. The device of claim 1, wherein the nanowire includes a metal nanowire doped with impurity or a semiconductor nanowire doped with impurity.

5. The device of claim 1, wherein the nanowire includes a nanowire or a plurality of nanowires.

6. The device of claim 5, wherein a diameter of the nanowire ranges from approximately 1 nm to approximately 30 nm.

7. The device of claim 1, wherein the resistive layer has two different resistance states respectively corresponding to generation and disappearance of a filament current path in a portion of the resistive layer that contacts the nanowire, upon application of a voltage across the nanowire and the upper electrode.

8. The device of claim 1, wherein the substrate includes a selectable transistor or a selectable diode and the nanowire electrically contacts the selectable transistor or the selectable diode.

9. A method of fabricating a resistive memory device, the method comprising:
forming a nanowire penetrating an insulation layer over a substrate to define a lower electrode;
forming a resistive layer over the insulation layer to contact the nanowire; and
forming an upper electrode over the resistive layer.

10. The method of claim 9, wherein the resistive layer include a binary oxide or a perovskite-based oxide.

11. The method of claim 9, wherein the forming of the nanowire comprises:
forming a catalyst layer over the substrate in a region where the nanowire is to be formed;
growing the nanowire from the catalyst layer to obtain a first resultant structure;
forming the insulation layer over the first resultant structure including the grown nanowire to obtain a second resultant structure; and
partially removing the insulation layer from the second resultant structure to expose an upper portion of the nanowire;
wherein the resistive layer is formed over the insulation layer to contact the nanowire at said exposed upper portion.

12. The method of claim 11, wherein said partially removing comprises planarizing the second resultant structure.

13. The method of claim 11, wherein the forming of the catalyst layer over the substrate comprises:
depositing a catalyst material over the substrate; and
patterning the catalyst material to remain in the region where the nanowire is to be formed, thereby obtaining the catalyst layer.

14. The method of claim 11, wherein the forming of the catalyst layer over the substrate comprises:
forming a lower insulation layer over the substrate while exposing the substrate in the region where the nanowire is to be formed; and
forming the catalyst layer over the exposed region of the substrate.

15. The method of claim 11, wherein the catalyst layer comprises a metal layer.

16. The method of claim 11, wherein the catalyst layer has a thickness ranging from approximately 10 Å to approximately 100 Å.

17. A method of forming an electrode for a resistive memory device that comprises a resistive layer sandwiched between said electrode and another electrode, said method comprising:
forming a catalyst layer over a substrate in a region where said electrode is to be formed;
growing a nanowire from the catalyst layer to form said electrode; and
burying the nanowire in an insulation layer.

18. The method of claim 17, wherein said burying comprises
forming the insulation layer over a first resultant structure including the grown nanowire to obtain a second resultant structure; and
partially removing the insulation layer from the second resultant structure to expose an upper portion of the nanowire where the resistive layer is to be formed over to contact the nanowire.

19. The method of claim 18, wherein said partially removing comprises planarizing the second resultant structure.

20. The method of claim 17, wherein the catalyst layer comprises a metal layer and has a thickness ranging from approximately 10 Å to approximately 100 Å.
